(19) United States
(12) Patent Application Publication
(10) Pub. No.: US 2005/0258552 A1
(43) Pub. Date: Nov. 24, 2005

(54) Semiconductor molding method and structure

(76) Inventor: Sung Jin Kim, Hsin-Chu (TW)

Correspondence Address: Mr. Eugene Lieberstein;ANDERSON KILL & OLICK, P.C., 1251 Avenue of Americas, New York, NY, 10020, US

(21) Appl. No.: 10/848,648

(22) Filed: May 18, 2004

(51) Int. Cl. H01L 23/48

(52) U.S. Cl. 257/787; 257/782

(57) ABSTRACT

A semiconductor molding method and structure, wherein a chip carrier is mounted with a plurality of semiconductor chips thereon, and encapsulation bodies are fabricated on the chip carrier to form a plurality of package units for respectively encapsulating the semiconductor chips. At least one pair of adjacent package units are connected together by at least one connective portion made of the encapsulation body, so as to prevent the semiconductor molding structure from warpage and deformation.

### FIELD OF THE INVENTION

The present invention relates to semiconductor molding methods and structures, and more particularly, to a molding method to reduce warpage and deformation of a semiconductor molding structure fabricated by the molding method.

### BACKGROUND OF THE INVENTION

Ball grid array (BGA) semiconductor package employs advanced packaging technology. As shown in FIG. 5, a substrate 51 is used as a carrier for a semiconductor chip 52, and a conductive trace layer 54 is formed respectively on an upper surface and a lower surface of the substrate 51. The chip 52 is electrically connected to the conductive trace layer 54 on the upper surface of the substrate 51 via bonding wires 53. A plurality of solder bumps 56 are implanted on the lower surface of the substrate 51 to transmit signals to the outside. And an encapsulation body 55 is formed on the upper surface of the substrate 51 to encapsulate the chip 52 and the bonding wires 53 and protect the semiconductor package 50.

The above BGA semiconductor package 50 is generally fabricated in a batch manner with concern of the fabrication cost and mass production, by which a substrate strip is used and defined with a plurality of array-arranged package units by multiple intercrossing border lines. Then, the substrate strip is subject to the die-bonding, wire-bonding and encapsulating processes. Finally, a singulation process is performed to separate apart the adjacent package units to produce a plurality of individual semiconductor packages 50 of FIG. 5.

Conventional for improving the fabrication efficiency and reduce the time and cost for forming the encapsulation body, a molding method for thin fine ball grid array (TFBGA) semiconductor packages is usually adopted for example as disclosed in U.S. Pat. No. 5,776,798. Referring to FIG. 6, a substrate 100 is defined with a plurality of array-arranged predetermined package sites (101, 102, 103, 104, 105, 106, etc.) that are bordered and separated from each other by gaps 107 surrounding the package sites. A dam bar 108 is formed peripherally around the substrate 100 and encompasses the plurality of package sites. As shown in FIG. 7, the substrate 100 is subject to a molding process strip by strip, allowing an encapsulating material such as epoxy resin to cover the package sites surrounded by the dam bar 108 so as to form an encapsulation body 109 that encapsulates the package sites on the substrate 100. By the provision of the dam bar 108 surrounding the plurality of package sites on the substrate 100, the fabricated encapsulation body 109 may preferably have a substantially flat top surface flush with the top of the dam bar 108. Finally, after a post-molding curing (PMC) process is carried out to form bonding of the epoxy resin, a singulation process is performed to cut the encapsulation body 109 and the substrate 100 at the gaps 107 so as to separate apart the package sites and produce a plurality of individually semiconductor packages of FIG. 5.

However, since the above predetermined package sites are arranged in arrays, the fabricated encapsulation body 109 covering all the package sites has a large surface area (generally 42.5 mm×42.5 mm). As a result, after performing the PMC process under a high temperature, warpage of the package structure may easily occur as shown in FIG. 7 due to different degrees of thermal expansion caused by mismatch in coefficient of thermal expansion (CTE) between the encapsulation body 109 and the substrate 100, the relatively small thickness of the substrate 100 for TFBGA packages, and a large contact area between the encapsulation body 109 and the substrate 100. The warpage would undesirably degrade the production yield and structural strength. Further since the warped structure has poor planarity, it is hard to be cut or singulated and may causes damage to the cutting tool.

Accordingly, referring to FIG. 8, U.S. Pat. No. 5,897,334 discloses the use of a substrate strip 61 defined with a plurality of square substrate units 62 bordered by package lines 63 and with connective portions 64 for connecting the adjacent substrate units 62 together. A chip 65 is mounted on each of the substrate units 62 and is electrically connected via bonding wires 66 to the corresponding substrate unit 62. Then, an encapsulating mold (not shown) is used for a molding process. The mold includes a plurality of cavities corresponding in position to the substrate units 62, to allow the substrate units 62 to be each molded to form individual package units 67 with separate encapsulation bodies 68 as shown in FIG. 9. This can effectively decrease the contact area between the encapsulation bodies 68 and the substrate strip 61, and allow thermal stresses to be released from gaps 69 between the encapsulation bodies 68 of the adjacent package units 67, thereby not leading to warpage shown in FIG. 7 caused by the CTE mismatch.

However, the above molding structure and method are still inherent with other structural drawbacks. After the molding process is complete, a user may usually move the molded substrate strip 61 by holding one end thereof to transfer the substrate strip 61 or change the jig so as to perform subsequent fabrication processes such as ball implantation, reliability tests, singulation or transfer on the substrate strip 61. Since the encapsulation bodies 68 of the individual package units 67 on the substrate strip 61 are separate, as shown in FIG. 10 (if the user holds the right end of the substrate strip 61), the substrate strip 61 acts as cantilever and is deformed or bent due to gravity attraction for the package units 67 at the left end of the substrate strip 61. As a result, the substrate strip 61 would be damaged if subject to long-term gravity force, and cracks or delamination may occur between the encapsulation body 68 and the corresponding chip 65, thereby adversely affecting the yield of the entire structure.

Therefore, the problem to be solved here is to provide a semiconductor molding method and structure, which can solve the above prior-art drawbacks to prevent structural warpage caused by CTE mismatch and to avoid structural deformation due to gravity force.

### SUMMARY OF THE INVENTION

A primary objective of the present invention is to provide a semiconductor molding method and structure, which can prevent structural warpage caused by mismatch in coefficient of thermal expansion (CTE).

Another objective of the present invention is to provide a semiconductor molding method and structure, which can prevent deformation caused by gravity force.

A further objective of the present invention is to provide a semiconductor molding method and structure, which can improve the structural strength and the yield.

In accordance with the above and other objectives, the present invention proposes a semiconductor molding method, comprising the steps of: preparing a chip carrier with a plurality of semiconductor chips mounted thereon, wherein the semiconductor chips are electrically connected to the chip carrier; performing a molding process to fabricate a plurality of encapsulation bodies on the chip carrier to form a plurality of package units for respectively encapsulating the semiconductor chips, wherein at least one connective portion is provided between at least one pair of the adjacent package units, and the connective portion is made of an encapsulating material for fabricating the encapsulation bodies; and performing a de-molding process to produce a semiconductor molding structure.

A semiconductor molding structure proposed in the present invention comprises a chip carrier; a plurality of semiconductor chips mounted on the chip carrier and electrically connected to the chip carrier; a plurality of encapsulation bodies fabricated on the chip carrier to form a plurality of package units for respectively encapsulating the semiconductor chips; and at least one connective portion provided between at least one pair of the adjacent package units, wherein the connective portion is made of an encapsulating material for fabricating the encapsulation bodies.

The foregoing connective portion is fabricated by filling a pre-formed connective via in a mold with the encapsulating material in the molding process. The connective portion is shaped as a strip, and a height of the connective portion is smaller than that of the package units. Every two adjacent package units are set as a pair, and the connective portion is provided between the two package units of each pair but not between the adjacent pairs of package units. Alternatively, the connective portion can be formed between any two of the adjacent package units.

Therefore, the semiconductor molding method and structure according to the present invention, in the use of the connective portion, can desirably stabilize the entire structure, prevent the occurrence of structural warpage due to CTE mismatch, and eliminate the structural deformation caused by the gravity force or attraction to solve the prior-art drawbacks, thereby effectively improving the structural strength and the production yield.

### BRIEF DESCRIPTION OF THE DRAWINGS

The present invention can be more fully understood by reading the following detailed description of the preferred embodiments, with reference made to the accompanying drawings, wherein:

FIGS. 1A and 1B are schematic diagrams showing a semiconductor molding method and structure according to a preferred embodiment of the present invention;

FIG. 2 is a top view of the molding structure shown in FIG. 1B;

FIGS. 3A and 3B are schematic diagrams showing a semiconductor molding method and structure according to another preferred embodiment of the present invention;

FIG. 4 is a top view of the molding structure shown in FIG. 3B;

FIG. 5 (PRIOR ART) is a cross-sectional view of a conventional BGA semiconductor package;

FIG. 6 (PRIOR ART) is a top view of a conventional substrate;

FIG. 7 (PRIOR ART) is a cross-sectional view showing warpage of the substrate of FIG. 6 after a molding process;

FIG. 8 (PRIOR ART) is a top view of a conventional substrate strip;

FIG. 9 (PRIOR ART) is a cross-sectional view showing the substrate strip of FIG. 8 after a molding process; and

FIG. 10 (PRIOR ART) is a cross-sectional view showing warpage of the substrate strip of FIG. 8 after molding.

### DETAILED DESCRIPTION OF THE PREFERRED EMBODIMENTS

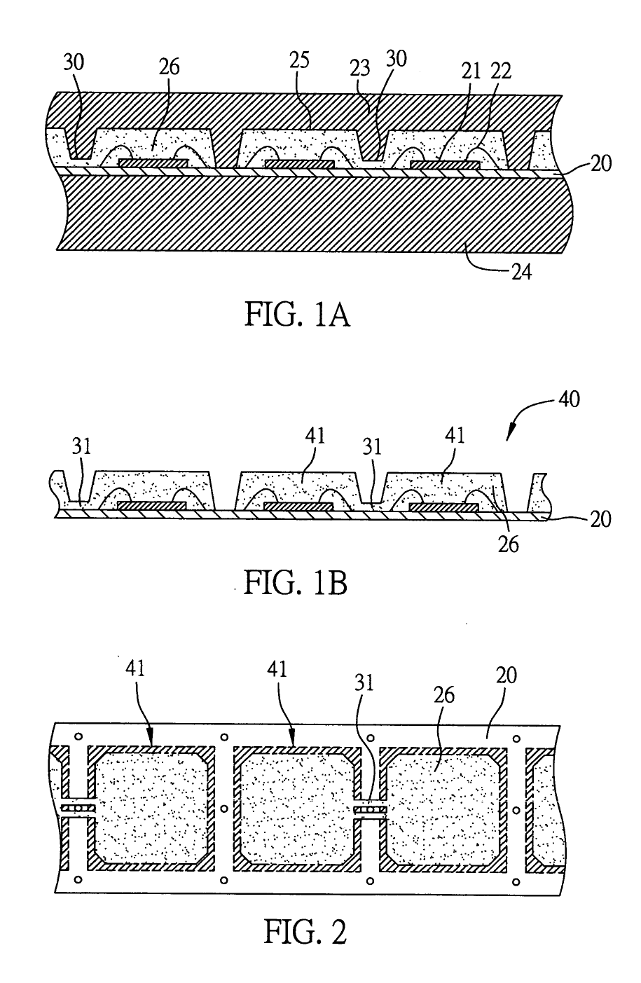

The preferred embodiments of a semiconductor molding method and structure proposed in the present invention are described in detail as follows with reference to FIGS. 1 to 4.

Referring to FIG. 1A, a chip carrier 20 such as a thin fine ball grid array (TFBGA) substrate is provided, wherein multiple intercrossing predetermined cutting lines are formed on a surface of the chip carrier 20 to define a plurality of array-arranged carrier sites for accommodating semiconductor chips 21 and final cutting paths on the chip carrier 20. The semiconductor chips 21 are electrically connected to conductive traces on the chip carrier 20 via bonding wires 22. Then, a molding process proposed in the present invention is performed. The chip carrier 20 is interposed and clamped between a specific upper mold 23 and a lower mold 24, wherein each chip 21 and the corresponding bonding wires 22 are received in one of cavities 25 of the upper mold 23. Further, every two adjacent cavities 25 are set as a pair, and between the two cavities 25 of each pair there are formed two connective vias 30 in the upper mold 23, the connective vias 30 having a height smaller than that of the cavities 25; however no connective via is provided between the adjacent pairs of cavities 25. As such, an encapsulating material for fabricating encapsulation bodies 26 can be injected into the cavities 25 via a gate (not shown) and filled in the two connective vias 30.

When all the cavities 25 and the connective vias 30 are fully filled with the encapsulation bodies 26, as shown in FIG. 1B, a de-molding process is performed to remove the molds 23, 24 and obtain a semiconductor device 40 comprising a plurality of package units 41, wherein every two adjacent package units 41 are set as a pair, and the two package units 41 of each pair are connected together by two connective portions 31 that are made by the encapsulation bodies 26 filled in the above two connective vias 30 of the upper mold 23; however no connective portion is formed between the adjacent pairs of package units 41. Thereby, the encapsulation bodies 26 for encapsulating two adjacent chips 21 are integrally formed on the chip carrier 20 by means of the connective portions 31. As shown in FIG. 2, the design and shape of the connective portions 31 can be clearly observed that, the connective portions 31 made of the encapsulating material for the encapsulation bodies correspond to the connective vias 30 of the upper mold 23 (FIG. 1A), and are shaped as two strips and spaced apart from each other by a predetermined distance, allowing the connective portions 31 to connect middle positions of the encapsulation bodies 26 of the two adjacent package units 41 together. As a result, the contact area between the chip carrier 20 and all the encapsulation bodies 26 would not be too large, and the connective portions 31 exert constraint force on the two adjacent package units 41 interconnected by the connective portions 31, so as to prevent structural deformation of the chip carrier 20 due to gravity force for the package units 41 located at two ends of the chip carrier 20.

Therefore, the above connective vias 30 in the upper mold 23 forms the two strip-shaped connective portions 31 between the two adjacent package units 41. Since the contact area between the connective portions 31 and the chip carrier 20 is not large, the encapsulation bodies 26 would not be restrained from thermal expansion but rather release their thermal expansion via sides of the connective portions 31, such that structural warpage caused by CTE mismatch between the encapsulation bodies 26 and the chip carrier 20 can also be avoided. Moreover, the connective portions 31 connecting the two adjacent package units 41 together exert appropriate constraint force on the package units 41 especially located at the two ends of the chip carrier 20 to counteract the gravity attraction for the end-situated package units 41, thereby eliminating the structural deformation caused by the gravity force. This desirably solves the prior-art problems, and also the constraint force applied to the adjacent package units 41 interconnected by connective portions 31 can be optimally controlled to stabilize the entire molding structure.

After the foregoing semiconductor device 40 is fabricated by molding, it is subject to other subsequent fabrication processes such as ball implantation, singulation, reliability tests, etc. to produce a plurality of TFBGA semiconductor packages; these fabrication processes are conventional and not to be further described. In addition, the encapsulating material for the encapsulation bodies 26 includes, but not limited to, a thermosetting resin such as epoxy resin or a thermoplastic resin such as polycarbonate ester, acrylate resin, polychloromethylene and polyester resin.

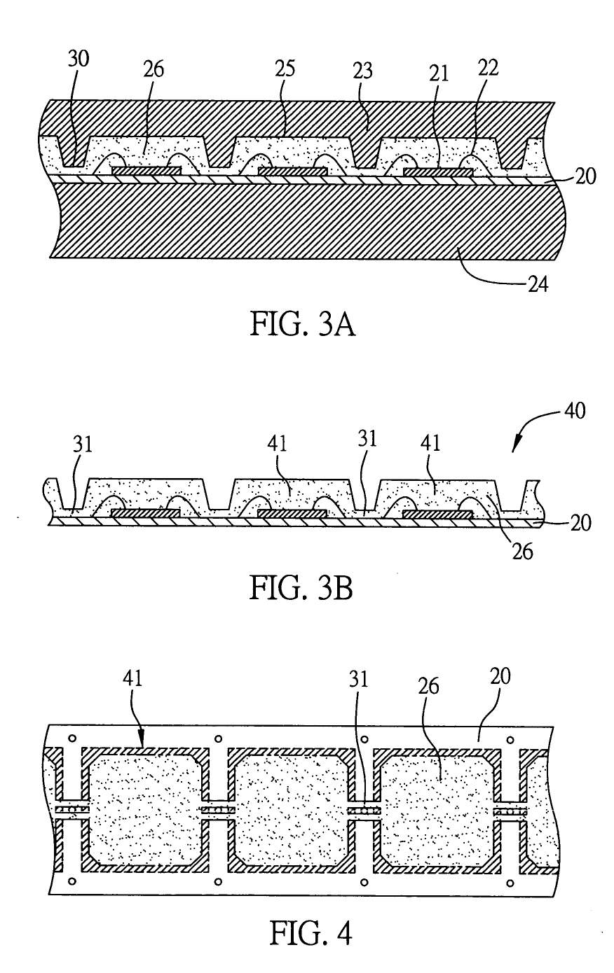

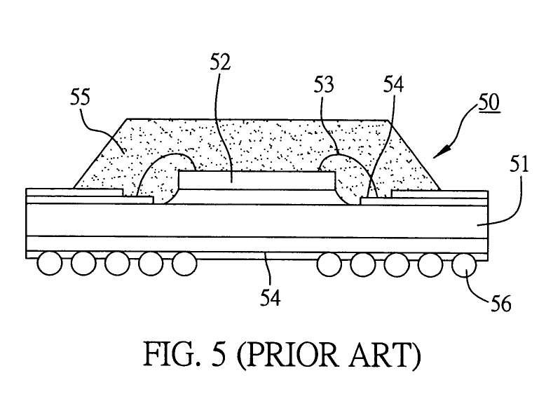

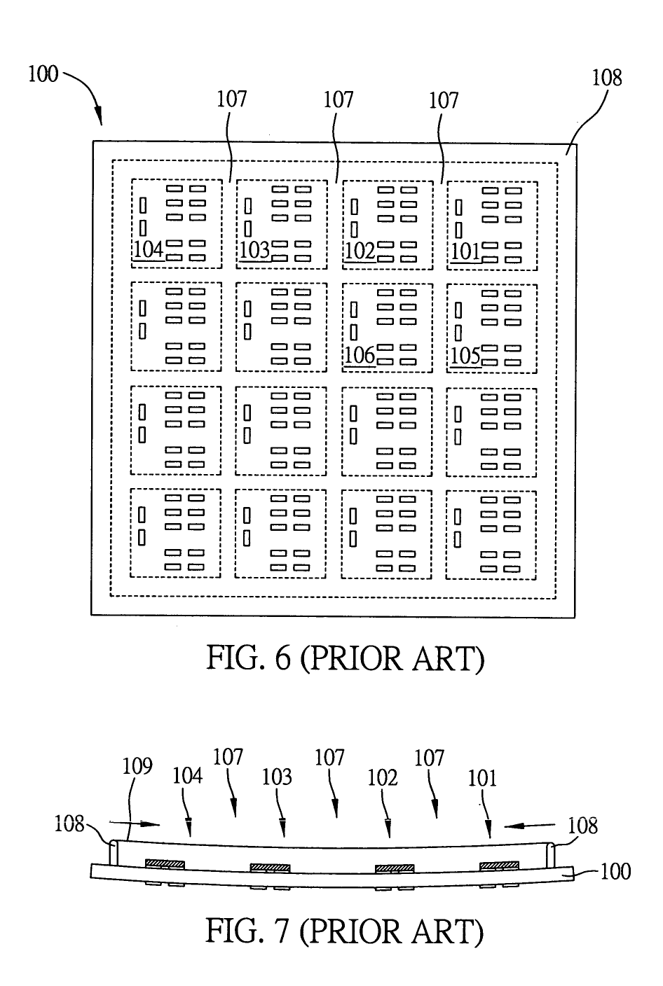

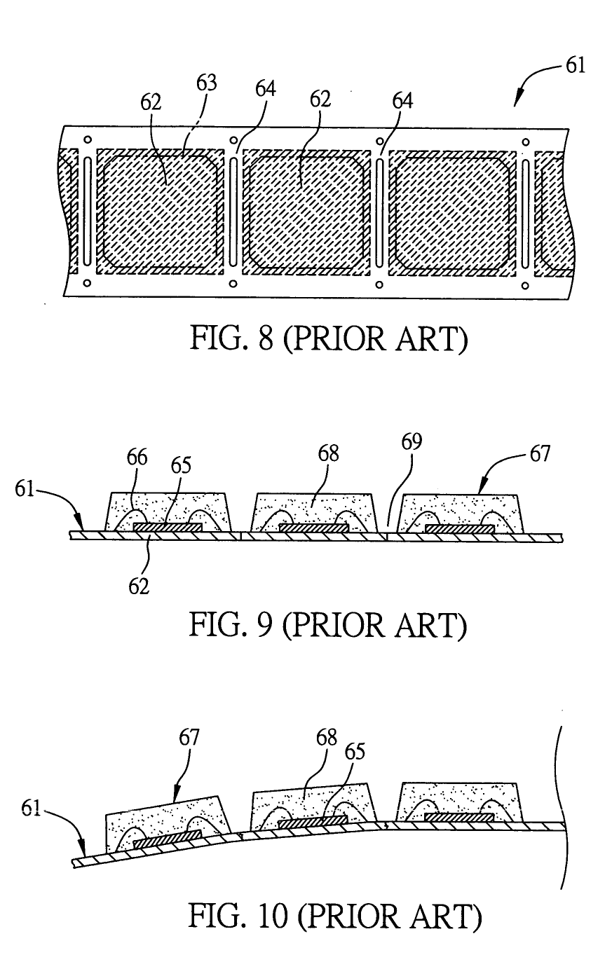

The semiconductor molding method and structure proposed in the present invention are not limited to the foregoing embodiment. Referring to FIG. 3A, the design of connective vias 30 in the upper mold 23 can be altered to provide two connective vias 30 between any two adjacent cavities 25, such that all the cavities 25 and the connective vias 30 are fully filled with the encapsulation bodies 26 during the molding process. After de-molding, as shown in FIG. 3B, the fabricated package units 41 comprises the plurality of encapsulation bodies 26 that are interconnected by the connective portions 31 made of the encapsulation bodies 26, and thus all the encapsulation bodies 26 are integrally formed on the chip carrier 20 for encapsulating all the chips 21. Referring to FIG. 4, since the two connective portions 31 between any two adjacent encapsulation bodies 26 are shaped as two strips and spaced apart from each other by a predetermined distance, the contact area between the integrally formed encapsulation bodies 26 and the chip carrier 20 would not be too large, and similarly to the above embodiment, appropriate constraint force can be exerted from the connective portions 31 on the adjacent package units 41 so as to prevent warpage and deformation of the molding structure caused by CTE mismatch and gravity force, making the entire structure stabilized.

Therefore, the semiconductor molding method and structure according to the present invention, in the use of the connective portions, can desirably stabilize the entire structure, prevent the occurrence of structural warpage due to CTE mismatch, and eliminate the structural deformation caused by the gravity force or attraction to solve the prior-art drawbacks, thereby effectively improving the structural strength and the production yield.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A semiconductor molding method comprising the steps of:
preparing a chip carrier with a plurality of semiconductor chips mounted thereon, wherein the semiconductor chips are electrically connected to the chip carrier;
performing a molding process to fabricate a plurality of encapsulation bodies on the chip carrier to form a plurality of package units for respectively encapsulating the semiconductor chips, wherein at least one connective portion is provided between at least one pair of the adjacent package units, and the connective portion is made of an encapsulating material for fabricating the encapsulation bodies; and
performing a de-molding process to produce a semiconductor molding structure.

2. The semiconductor molding method of claim 1, wherein the connective portion is formed by filling at least one pre-formed connective via in a mold with the encapsulating material during the molding process.

3. The semiconductor molding method of claim 1, wherein the adjacent package units are interconnected via two connective portions that are spaced apart from each other by a predetermined distance.

4. The semiconductor molding method of claim 1, wherein the connective portion is shaped as a strip.

5. The semiconductor molding method of claim 1, wherein a height of the connective portion is smaller than that of the package units.

6. The semiconductor molding method of claim 1, wherein every two adjacent package units are set as a pair, and the connective portion is provided between the two package units of each pair, free of the connective portion between the adjacent pairs of package units.

7. The semiconductor molding method of claim 1, wherein the connective portion is formed between any two of the adjacent package units.

8. The semiconductor molding method of claim 1, wherein the chip carrier is a thin fine ball grid array substrate.

9. The semiconductor molding method of claim 1, wherein multiple intercrossing cutting lines are provided on the chip carrier to define a plurality of package sites on the chip carrier corresponding to the package units.

10. The semiconductor molding method of claim 1, wherein the semiconductor chips are electrically connected to the chip carrier by bonding wires.

11. A semiconductor molding structure comprising:
a chip carrier;
a plurality of semiconductor chips mounted on the chip carrier and electrically connected to the chip carrier;
a plurality of encapsulation bodies fabricated on the chip carrier to form a plurality of package units for respectively encapsulating the semiconductor chips; and
at least one connective portion provided between at least one pair of the adjacent package units, wherein the connective portion is made of an encapsulating material for fabricating the encapsulation bodies.

12. The semiconductor molding structure of claim 11, wherein the adjacent package units are interconnected via two connective portions that are spaced apart from each other by a predetermined distance.

13. The semiconductor molding structure of claim 11, wherein the connective portion is shaped as a strip.

14. The semiconductor molding structure of claim 11, wherein a height of the connective portion is smaller than that of the package units.

15. The semiconductor molding structure of claim 11, wherein every two adjacent package units are set as a pair, and the connective portion is provided between the two package units of each pair, free of the connective portion between the adjacent pairs of package units.

16. The semiconductor molding structure of claim 11, wherein the connective portion is formed between any two of the adjacent package units.

17. The semiconductor molding structure of claim 11, wherein the chip carrier is a thin fine ball grid array substrate.

18. The semiconductor molding structure of claim 11, wherein multiple intercrossing cutting lines are provided on the chip carrier to define a plurality of package sites on the chip carrier corresponding to the package units.

19. The semiconductor molding structure of claim 11, wherein the semiconductor chips are electrically connected to the chip carrier by bonding wires.
